(19) United States
(12) Patent Application Publication
(10) Pub. No.: US 2023/0063639 A1
(43) Pub. Date: Mar. 2, 2023

(54) HEAT TREATMENT UNIT AND SUBSTRATE PROCESSING APPARATUS

(71) Applicant: SEMES CO., LTD., Cheonan-si (KR)

(72) Inventors: Gyeong Won SONG, Cheonan-si (KR); Jae Seong LEE, Hwaseong-si (KR); Chun Woo PARK, Yongin-si (KR)

(21) Appl. No.: 17/898,459

(22) Filed: Aug. 29, 2022

(30) Foreign Application Priority Data
Sep. 2, 2021 (KR) 10-2021-0117222

(51) Int. Cl. B05D 3/02

(52) U.S. Cl. CPC B05D 3/0218

(57) ABSTRACT

Provided is a heat treatment unit, including: a chamber providing a substrate processing apparatus including: a process chamber in which an upper chamber and a lower chamber are in contact with each other to form a treatment space defined by the upper chamber and the lower chamber; a heating plate positioned in the treatment space to heat a substrate; a lift pin for placing the substrate on the heating plate or for moving the substrate placed on the heating plate to be spaced apart from the heating plate; a driving member connected to the upper chamber or the lower chamber to vertically drive the upper chamber or the lower chamber; an exhaust member connected to a central region of the upper chamber to exhaust the treatment space; and an airflow blocking member provided on an upper surface of the heating plate and formed to surround an edge of the substrate so as to block a surrounding airflow from approaching the edge of the substrate.

### CROSS-REFERENCE TO RELATED APPLICATIONS

This application claims priority to and the benefit of Korean Patent Application No. 10-2021-0117222 filed in the Korean Intellectual Property Office on Sep. 2, 2021, the entire contents of which are incorporated herein by reference.

### TECHNICAL FIELD

The present invention relates to a heat treatment unit and a substrate processing apparatus.

### BACKGROUND ART

In order to manufacture a semiconductor device, various processes, such as cleaning, deposition, photography, etching, and ion implantation, are performed. Among these processes, a deposition and coating process is used as a process for forming a film on a substrate. In general, the deposition process is a process of forming a film by depositing process gas on a substrate, and the coting process is a process of forming a liquid film by applying a processing liquid on the substrate.

Before and after forming the film on the substrate, a process of baking the substrate is performed. The baking process is a process of heating the substrate to a process temperature or higher, and the entire region of the substrate is heated to a uniform temperature or the temperature of each region of the substrate is adjusted according to an operator.

However, outside air flows into a bake treating apparatus. Due to this, the outside air is preferentially in contact with an edge region of the substrate W, and after the outside air in contact with an inner region of the substrate W, the outside air is exhausted through an upper central region of a chamber.

That is, in the bake treating apparatus in the related art, the edge of the substrate has a lot of contact with the surrounding cold air (airflow) during the substrate heat treatment process, so that more heat is lost in the edge region of the substrate than the central region of the substrate. Accordingly, there is a problem in that the temperature of the edge region of the substrate having a large contact area with the surrounding atmosphere is lower than that of the central region of the substrate.

### SUMMARY OF THE INVENTION

The present invention has been made in an effort to provide a heat treatment unit and a substrate processing apparatus capable of minimizing the access of surrounding atmosphere to an edge region of a substrate.

The present invention has also been made in an effort to provide a heat treatment unit and a substrate processing apparatus capable of uniformly controlling the temperature of each region of a substrate.

The problem to be solved by the present invention is not limited to the above-mentioned problems. The problems not mentioned will be clearly understood by those skilled in the art from the descriptions below.

An exemplary embodiment of the present invention provides a heat treatment unit, including: a chamber providing a heat treatment space; a heating plate which is provided inside the chamber and on which a substrate is seated; and an airflow blocking member provided to the heating plate and provided to surround an edge of the substrate to block a surrounding airflow from approaching the edge of the substrate.

Further, the airflow blocking member may include a heating element for preventing a temperature drop of the edge of the substrate.

Further, the airflow blocking member may be divided into a plurality of sections, and the heating element may be provided in each section to be independently controllable.

Further, the airflow blocking member may be provided in a ring shape.

Further, an upper surface of the airflow blocking member may be provided at a height equal to or higher than a height of an upper surface of the substrate seated on the heating plate.

Further, the airflow blocking member may have a curved upper surface.

Further, in the airflow blocking member, one side facing the edge of the substrate and the other side opposite to the one side may have different inclinations from each other.

Further, the inclination of the other side may be provided more gently than the inclination of the one side.

Another exemplary embodiment of the present invention provides a substrate processing apparatus, including: a process chamber in which an upper chamber and a lower chamber are in contact with each other to form a treatment space defined by the upper chamber and the lower chamber; a heating plate positioned in the treatment space to heat a substrate; a lift pin for placing the substrate on the heating plate or for moving the substrate placed on the heating plate to be spaced apart from the heating plate; a driving member connected to the upper chamber or the lower chamber to vertically drive the upper chamber or the lower chamber; an exhaust member connected to a central region of the upper chamber to exhaust the treatment space; and an airflow blocking member provided on an upper surface of the heating plate and formed to surround an edge of the substrate so as to block a surrounding airflow from approaching the edge of the substrate.

Further, the airflow blocking member may include a heating element for preventing a temperature drop of the edge of the substrate.

Further, the airflow blocking member may be divided into a plurality of sections, and the heating element may be provided in each section to be independently controllable.

Further, the airflow blocking member may have an annular ring shape.

Further, an upper surface of the airflow blocking member may be provided at a height equal to or higher than a height of an upper surface of the substrate seated on the heating plate.

Further, the airflow blocking member may have a curved upper surface.

Further, in the airflow blocking member, one side facing the edge of the substrate and the other side opposite to the one side may have different inclinations from each other.

Further, the inclination of the other side may be provided more gently than the inclination of the one side.

Still another exemplary embodiment of the present invention provides a substrate processing apparatus, including: a housing providing a heat treatment space therein and having a slot for loading and unloading the substrate on one side; a cooling unit located in the heat treatment space of the housing to cool the substrate; a heating unit located at one side of the cooling unit and heating the substrate; and a transfer unit for transferring a substrate between the cooling unit and the heating unit, in which the heating unit includes: a process chamber in which an upper chamber and a lower chamber are in contact with each other to form a treatment space defined by the upper chamber and the lower chamber; a heating plate positioned in the treatment space to heat a substrate; a lift pin for placing the substrate on the heating plate or for moving the substrate placed on the heating plate to be spaced apart from the heating plate; a driving member connected to the upper chamber or the lower chamber to vertically drive the upper chamber or the lower chamber; an exhaust member connected to a central region of the upper chamber to exhaust the treatment space; and an airflow blocking member provided on an upper surface of the heating plate and formed to surround an edge of the substrate so as to block a surrounding airflow from approaching the edge of the substrate.

Further, the airflow blocking member may include a heating element for preventing a temperature drop of the edge of the substrate.

Further, the airflow blocking member is divided into a plurality of sections, and the heating element is provided in each section to be independently controllable.

Further, the airflow blocking member may have an annular ring shape, and an upper surface of the airflow blocking member may be provided at a height equal to or higher than a height of an upper surface of the substrate seated on the heating plate.

According to the exemplary embodiment of the present invention, it is possible to uniformly control the temperature of each region of the substrate by minimizing the approach of the surrounding atmosphere to the edge region of the substrate.

The effect of the present invention is not limited to the foregoing effects. Those skilled in the art may clearly understand non-mentioned effects from the present specification and the accompanying drawings.

### BRIEF DESCRIPTION OF THE DRAWINGS

FIG. 1 is a perspective view schematically illustrating a substrate processing apparatus according to an exemplary embodiment of the present invention.

FIG. 2 is a cross-sectional view of the substrate processing apparatus illustrating a coating block or a developing block of FIG. 1.

FIG. 3 is a top plan view of the substrate processing apparatus of FIG. 1.

FIG. 4 is a diagram illustrating an example of a hand of a transfer robot.

FIG. 5 is a cross-sectional view illustrating an exemplary embodiment of a liquid processing chamber for liquid-processing a substrate by supplying a processing liquid to a rotating substrate.

FIG. 6 is a top plan view of the liquid processing chamber of FIG. 5.

FIG. 7 is a perspective view illustrating an example of the transfer robot of FIG. 3.

FIG. 8 is a top plan view schematically illustrating an example of the heat treatment chamber of FIG. 3.

FIG. 9 is a front view of the heat treatment chamber of FIG. 8.

FIG. 10 is a diagram illustrating a transfer plate of FIG. 8.

FIG. 11 is a diagram illustrating the substrate processing apparatus provided in a heating unit of FIG. 9.

FIG. 12A is a diagram of a support unit of FIG. 11 when viewed from the top, and FIG. 12B is an enlarged diagram of the main part of FIG. 11.

FIG. 13 is a diagram illustrating an influence of an airflow blocking member on a temperature distribution of an edge of the substrate.

FIG. 14 is a diagram illustrating a second exemplary embodiment of the airflow blocking member.

FIG. 15 is a diagram illustrating a modified example of the airflow blocking member.

FIG. 16 is a view illustrating another modified example of the airflow blocking member.

FIG. 17 is a view illustrating another modified example of the airflow blocking member.

### DETAILED DESCRIPTION

Advantages and characteristics, and a method for achieving them will be clear when exemplary embodiments described in detail with reference to the accompanying drawings are referred to. However, the present disclosure is not limited to exemplary embodiments disclosed herein but will be implemented in various forms, and the exemplary embodiments are provided so that the present disclosure is completely disclosed, and a person of ordinary skilled in the art can fully understand the scope of the present disclosure, and the present disclosure will be defined only by the scope of the appended claims.

Even if not defined, all terms (including technical or scientific terms) used herein have the same meaning as commonly accepted by common skill in the related art to which this invention belongs. Terms defined by the general dictionaries may be interpreted as having the same meaning as in the related art and/or in the text of the present application, and the terms will not be conceptualized or interpreted overly formal even if the term is not a clearly defined expression here. The terms used in the present specification is for the purpose of describing exemplary embodiments, and do not intend to limit the present invention.

In the present specification, a singular form includes a plural form as well, unless otherwise mentioned. A term “include” and/or various conjugations of this verb do not exclude the existence or an addition of one or more other compositions, components, constituent elements, steps, operations, and/or devices, in addition to the mentioned composition, component, constituent element, step, operation, and/or device. Further, “is provided” and “have” and the like should be interpreted in the same way.

The equipment of the present exemplary embodiment is described as being used to perform a photolithography process on a substrate, such as a semiconductor wafer or a flat panel display panel, but this is for convenience of description and the present invention may also be used in other apparatuses including robots that transfer substrates to process substrates.

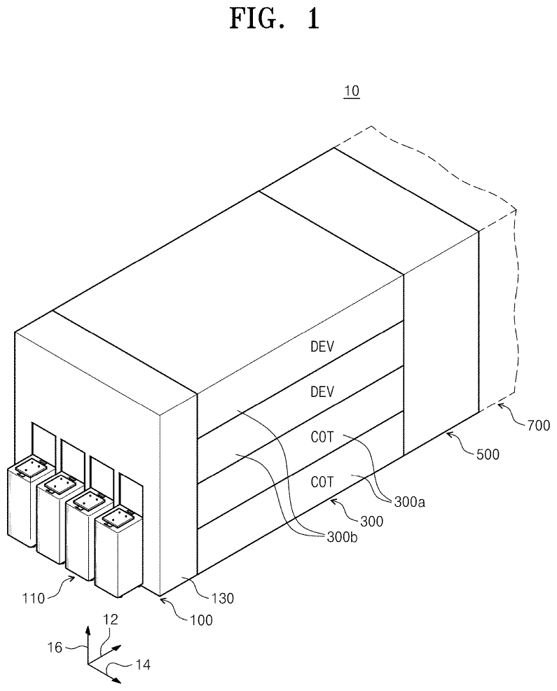

Hereinafter, an exemplary embodiment of the present invention will be described in detail with reference to FIGS. 1 to 15.

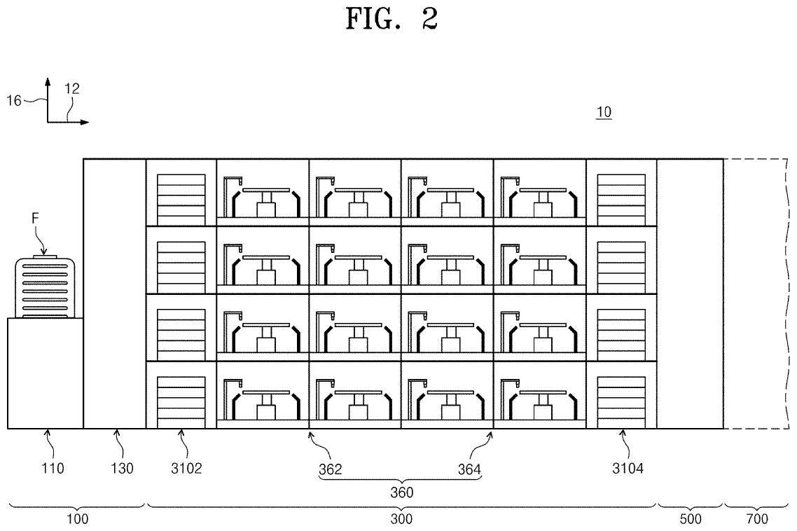

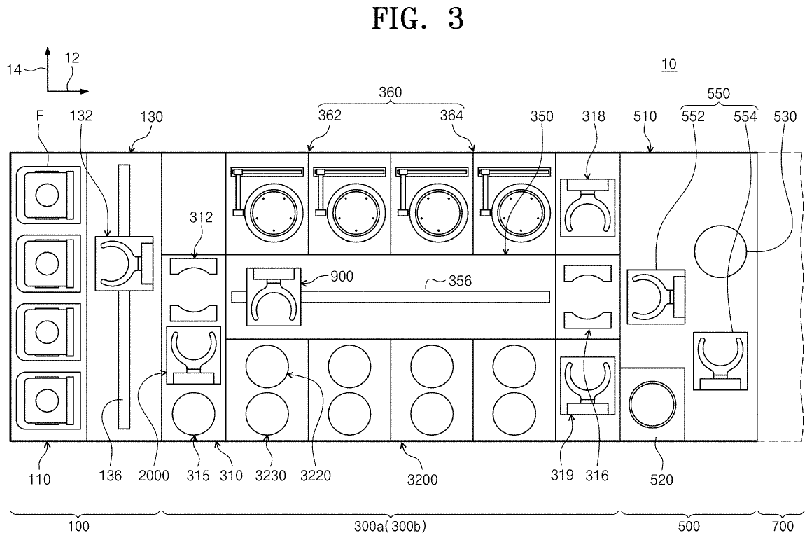

FIG. 1 is a perspective view schematically illustrating a substrate processing apparatus according to an exemplary embodiment of the present invention, FIG. 2 is a cross-sectional view of the substrate processing apparatus illustrating a coating block or a developing block of FIG. 1, and FIG. 3 is a top plan view of the substrate processing apparatus of FIG. 1.

Referring to FIGS. 1 to 3, a substrate processing apparatus 10 according to the exemplary embodiment of the present invention includes an index module 100, a processing module 300, and an interface module 500.

According to the exemplary embodiment, the index module 100, the processing module 300, and the interface module 500 are sequentially arranged in a line. Hereinafter, the direction in which the index module 100, the processing module 300, and the interface module 500 are arranged is called a first direction 12, and when viewed from the top, a direction perpendicular to the first direction 12 is defined as a second direction 14, and a direction perpendicular to both the first direction 12 and the second direction 14 is defined as a third direction 16.

The index module 100 transfers a substrate W to the processing module 300 from a container F in which the substrate W is accommodated, and receives the completely treated substrate W into the container F. A longitudinal direction of the index module 100 is provided in the second direction 14. The index module 100 includes a load port 110 and an index frame 130. With respect to the index frame 130, the load port 110 is located on the opposite side of the processing module 300. The container F in which the substrates W are accommodated is placed on the load port 110. A plurality of load ports 110 may be provided, and the plurality of load ports 110 may be disposed along the second direction 14.

As the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. A guide rail 136 of which a longitudinal direction is provided in the second direction 14 is provided within the index frame 130, and the index robot 132 may be provided to be movable on the guide rail 136. The index robot 132 includes a hand on which the substrate W is placed, and the hand is provided to be movable forward and backward, rotatable about the third direction 16, and movable in the third direction 16.

The processing module 300 may perform a coating process and a developing process on the substrate W. The processing module 300 may receive the substrate W accommodated in the container F and perform a substrate processing process. The processing module 300 includes a coating block 300a, a developing block 300b, and a front buffer chamber 310.

The costing block 300a performs an application process on the substrate W, and the developing block 300b performs a developing process on the substrate W. A plurality of coating blocks 300a is provided, and the coating blocks 300a are provided to be stacked on each other. A plurality of developing blocks 300b is provided, and the developing blocks 300b are provided to be stacked on each other. According to the exemplary embodiment of FIG. 1, two coating blocks 300a and two developing blocks 300b are provided respectively. The coating blocks 300a may be disposed under the developing blocks 300b. According to an example, the two coating blocks 300a perform the same process, and may be provided in the same structure. Further, the two developing blocks 300b may perform the same process and may be provided in the same structure.

Referring to FIG. 3, the coating block 300a includes a heat treatment chamber 320, a transfer chamber 350, and a liquid processing chamber 360.

The heat treatment chamber 320 performs a heat treatment process on the substrate W. The heat treatment process may include a cooling process and a heating process. The liquid processing chamber 360 supplies a liquid on the substrate W to form a liquid film. The liquid film may be a photoresist film or an antireflection film. The transfer chamber 350 transfers the substrate W between the heat treatment chamber 320 and the liquid processing chamber 360 in the coating block 300a.

The transfer chamber 350 is provided so that a longitudinal direction thereof is parallel to the first direction 12. The transfer robot 350 is provided to the transfer chamber 900. The transfer robot 352 transfers the substrate between the heat treatment chamber 320, the liquid processing chamber 360, and the buffer chambers 312 and 316. According to an example, the transfer robot 900 includes a hand on which the substrate W is placed, and the hand may be provided to be movable forward and backward, rotatable about the third direction 16, and movable in the third direction 16. A guide rail 356, of which a longitudinal direction is parallel to the first direction 12, is provided within the transfer chamber 350, and the transfer robot 900 may be provided to be movable on the guide rail 356.

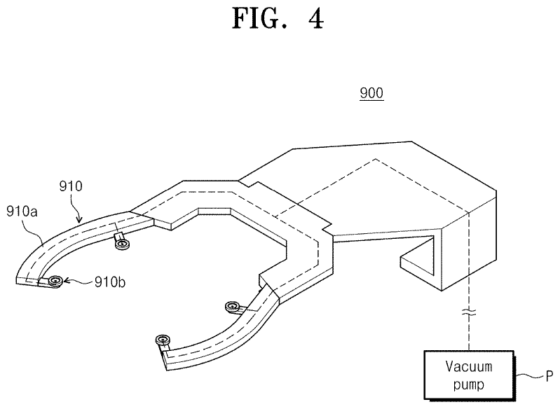

FIG. 4 is a diagram illustrating an example of the hand of the transfer robot.

Referring to FIG. 4, the hand 910 includes a hand main body 910a and support fingers 910b. The hand main body 910a is formed in a substantially horseshoe shape having an inner diameter greater than the diameter of the substrate. However, the shape of the hand main body 910a is not limited thereto. In four places including the leading end of the hand main body 910a, the support fingers 910b are installed inwardly. The hand main body 910a has a vacuum flow path (not illustrated) formed therein. A vacuum flow path (not illustrated) is connected to a vacuum pump through a vacuum line.

Referring back to FIGS. 1 to 3, a plurality of heat treatment chambers 320 is provided. The thermal processing chambers 320 are disposed along the first direction 12. The heat treatment chambers 320 are located at one side of the transfer chamber 350.

A plurality of liquid processing chambers 360 is provided. Some of the liquid processing chambers 360 may be provided to be stacked on each other. The liquid processing chambers 360 are disposed at one side of the transfer chamber 350. The liquid processing chambers 360 are arranged side by side along the first direction 12. Some of the liquid processing chambers 360 are provided at positions adjacent to the index module 100. Hereinafter, the liquid processing chambers 360 located to be adjacent to the index module 100 are referred to as front liquid processing chambers 362. Another some of the liquid processing chambers 360 are provided at positions adjacent to the interface module 500. Hereinafter, the liquid processing chambers 360 located to be adjacent to the interface module 500 are referred to as rear liquid processing chambers 364.

The front liquid processing chamber 362 applies a first liquid onto the substrate W, and the rear liquid processing chamber 284 applies a second liquid onto the substrate W. The first liquid and the second liquid may be different types of liquid. According to the exemplary embodiment, the first liquid is an antireflection film, and the second liquid is a photoresist. The photoresist may be applied onto the substrate W coated with the antireflection film. Optionally, the first liquid may be a photoresist, and the second liquid may be an antireflection film. In this case, the antireflection film may be applied onto the substrate W coated with the photoresist. Optionally, the first liquid and the second liquid are the same type of liquid, and both the first liquid and the second liquid may be the photoresist.

The developing block 300b has the same structure as the coating block 300a, and the liquid processing chamber provided in the developing block 300b supplies a developer on the substrate.

The interface module 500 connects the processing module 30 to an external exposing device 700. The interface module 500 includes an interface frame 510, an additional process chamber 520, an interface buffer 530, and an interface robot 550.

A fan filter unit for forming a descending airflow therein may be provided at an upper end of the interface frame 510. The additional process chamber 520, the interface buffer 530, and the interface robot 550 are disposed inside the interface frame 510. The additional process chamber 340 may perform a predetermined additional process before the substrate W, which has been completely treated in the coating block 300a, is loaded into the exposing device 700. Optionally, the additional process chamber 520 may perform a predetermined additional process before the substrate W, which has been completely processed in the exposing device 700, is loaded into the developing block 300b. According to one example, the additional process may be an edge exposure process of exposing an edge region of the substrate W, a top surface cleaning process of cleaning the upper surface of the substrate W, or a lower surface cleaning process of cleaning the lower surface of the substrate W. A plurality of additional process chambers 520 is provided, and may be provided to be stacked on each other. All of the additional process chambers 520 may be provided to perform the same process. Optionally, a part of the additional process chambers 520 may be provided to perform different processes.

The interface buffer 530 provides a space in which the substrate W transferred between the coating block 300a, the additional process chamber 520, the exposing device 700, and the developing block 300b temporarily stays during the transfer. A plurality of interface buffers 530 may be provided, and the plurality of interface buffers 530 may be provided to be stacked on each other.

According to the example, the additional process chamber 520 may be disposed on one side of the transfer chamber 350 based on an extended line in the longitudinal direction and the interface buffer 530 may be disposed on the other side thereof.

The interface robot 550 transfers the substrate W between the applying block 300a, the additional process chamber 520, the exposing device 700, and the developing block 300b. The interface robot 550 may have a transfer hand that transfers the substrate W. The interface robot 550 may be provided as one or a plurality of robots. According to the example, the interface robot 550 has a first robot 552 and a second robot 554. The first robot 552 may be provided to transfer the substrate W between the coating block 300a, the additional process chamber 520, and the interface buffer 530, and the second robot 554 may be provided to transfer the substrate W between the interface buffer 530 and the exposing device 700, and the second robot 554 may be provided to transfer the substrate W between the interface buffer 530 and the developing block 300b.

The first robot 552 and the second robot 554 each include a transfer hand on which the substrate W is placed, and the hand may be provided to be movable forward and backward, rotatable about an axis parallel to the third direction 16, and movable along the third direction 16.

Hereinafter, the structure of the liquid processing chamber will be described in detail. Hereinafter, the liquid processing chamber provided in the coating block will be described as an example. In addition, the liquid processing chamber will be described based on the case of a chamber for applying the photoresist onto the substrate as an example. However, the liquid processing chamber may be a chamber in which a film, such as a protective film or an antireflection film, is formed on the substrate W. In addition, the liquid processing chamber may be a chamber for developing the substrate W by supplying a developer to the substrate W.

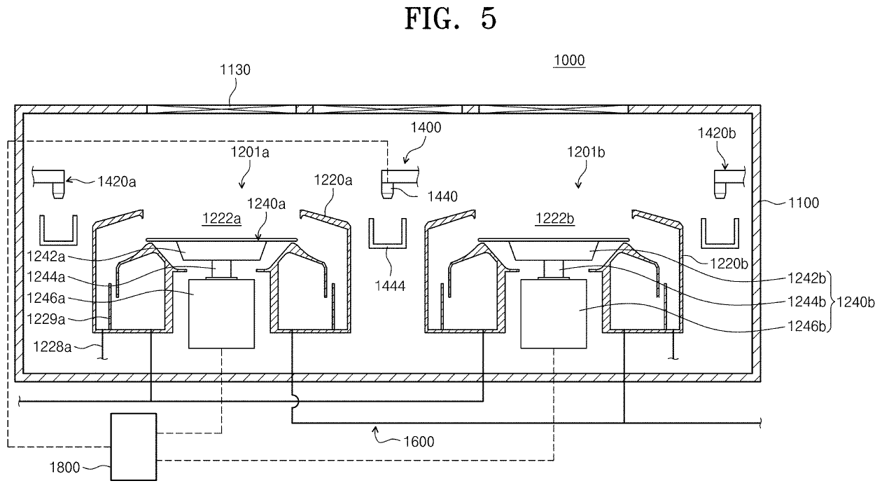

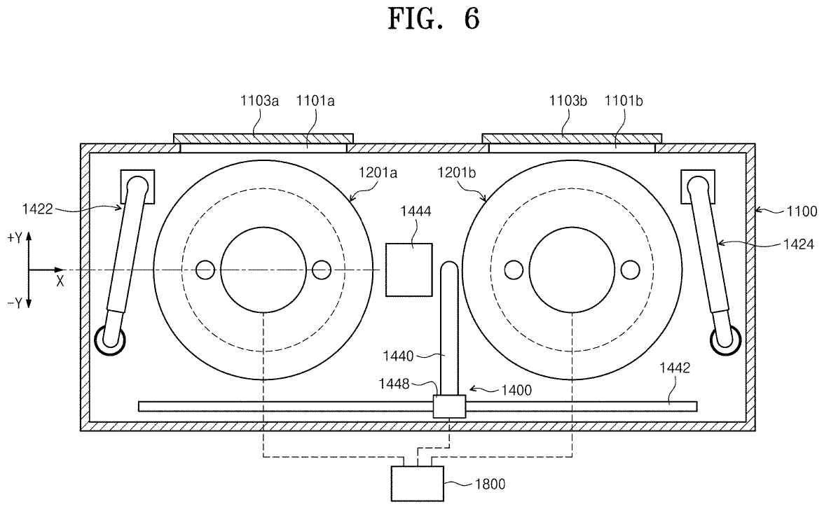

FIG. 5 is a cross-sectional view illustrating an exemplary embodiment of the liquid processing chamber for liquid-processing the substrate by supplying the processing liquid to the rotating substrate, and FIG. 6 is a top plan view of the liquid processing chamber of FIG. 5.

Referring to FIGS. 5 and 6, the liquid processing chamber 1000 includes a housing 1100, a first treatment unit 1201a, a second treatment unit 1201b, a liquid supply unit 1400, an exhaust unit 1600, and a controller 1800.

The housing 1100 is provided in a rectangular cylindrical shape having an inner space. Openings 1101a and 1101b are formed at one side of the housing 1100. The openings 1101a and 1101b function as passages through which the substrate W is loaded in and out. Doors 1103a and 1103b are installed in the openings 1101a and 1101b, and the doors 1103a and 1103b open and close the openings 1101a and 1101b.

A fan filter unit 1130 is disposed on the upper wall of the housing 1100 to supply a descending airflow into the inner space. The fan filter unit 1130 includes a fan for introducing external air into the inner space and a filter for filtering external air.

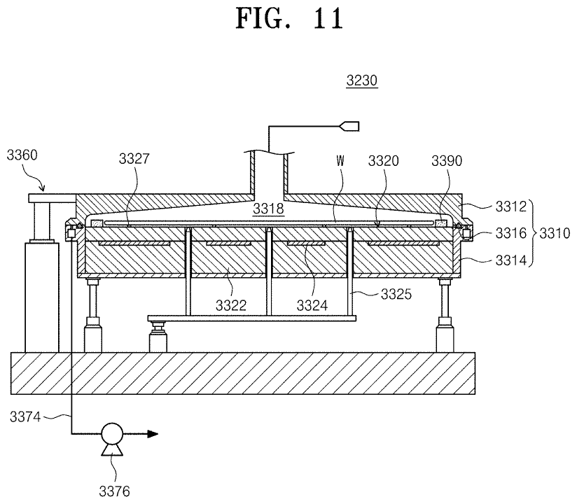

The first treatment unit 1201a and the second treatment unit 1201b are provided in the inner space of the housing 1100. The first treatment unit 1201a and the second treatment unit 1201b are arranged along one direction. Hereinafter, a direction in which the first treatment unit 1201a and the second treatment unit 1201b are arranged is referred to as a unit arrangement direction, and is illustrated in the X-axis direction in FIG. 11.

The first treatment unit 1201a has a first processing chamber 1220a and a first support unit 1240a.

The first processing container 1220a has a first inner space 1222a. The first inner space 1222a is provided with an open top.

The first support unit 1240a supports the substrate W in the first inner space 1222a of the first processing container 1220a. The first support unit 1240a includes a first support plate 1242a, a first drive shaft 1244a, and a first driver 1246a. The first supporting plate 1242a has a circular top surface. The first support plate 1242a has a smaller diameter than that of the substrate W. The first support plate 1242a is provided to support the substrate W by vacuum pressure. Optionally, the first support plate 1242a may have a mechanical clamping structure for supporting the substrate W. A first driving shaft 1244a is coupled to the center of the bottom surface of the first support plate 1242a, and a first driver 1246a for providing rotational force to the first driving shaft 1244a is provided to the first driving shaft 1244a. The first driver 1246a may be a motor.

The second processing unit 1201b includes a second processing container 1220b and a second support unit 1240b, and the second support unit 1240b includes a second support plate 1242b, a second drive shaft 1244b, and a second driver 1246b. The second processing container 1220b and the second supporting unit 1240b have substantially the same structure as the first processing container 1220a and the first supporting unit 1240a.

The liquid supply unit 1400 supplies the processing liquid onto the substrate W. The liquid supply unit 1400 includes a first nozzle 1420a, a second nozzle 1420b, and a processing liquid nozzle 1440. The first nozzle 1420a supplies a liquid to the substrate W provided in the first support unit 1240a, and the second nozzle 1420b supplies liquid to the substrate W provided in the second support unit 1240b. The first nozzle 1420a and the second nozzle 1420b may be provided to supply the same type of liquid. According to an example, the first nozzle 1420a and the second nozzle 1420b may supply a rinse liquid for cleaning the substrate W. For example, the rinse liquid may be water. According to another example, the first nozzle 1420a and the second nozzle 1420b may supply a removal liquid for removing the photoresist from the edge region of the substrate W. For example, the removal liquid may be a thinner. Each of the first nozzle 1420a and the second nozzle 1420b may be rotated between a process position and a standby position about a rotation axis thereof. The process position is a position at which the liquid is discharged onto the substrate W, and the standby position is a position at which the first nozzle 1420a and the second nozzle 1420b stand by without discharging the liquid onto the substrate W.

The processing liquid nozzle 1440 supplies the processing liquid to the substrate W provided in the first support unit 1240a and the substrate W provided in the second support unit 1240b. The treatment solution may be a photoresist. The nozzle driver 1448 drives the processing liquid nozzle 1440 so that the processing liquid nozzle 1440 moves between a first process position, the standby position, and a second process position along a guide 1442. The first process position is a position for supplying the processing liquid to the substrate W supported by the first support unit 1240a, and the second process position is a position for supplying the processing liquid to the substrate W supported by the second support unit 1240b. The standby position is a position in which the nozzle waits the standby port 1444 located between the first processing unit 1201a and the second processing unit 1201b when the photoresist is not discharged from the processing liquid nozzle 1440.

A gas-liquid separation plate 1229a may be provided in the inner space 1201a of the first processing container 1220a. The gas-liquid separation plate 1229a may be provided to extend upwardly from the bottom wall of the first processing container 1220a. The gas-liquid separation plate 1229a may be provided in a ring shape.

According to the example, the outside of the gas-liquid separation plate 1229a may be provided as a discharging space for discharging the liquid, and the inside of the gas-liquid separation plate 1229a may be provided as an exhaust space for exhausting the atmosphere. A discharge pipe 1228a for discharging the processing liquid is connected to the bottom wall of the first processing container 1220a. The discharge pipe 1228a discharges the processing liquid introduced between the sidewall of the first processing container 1220a and the gas-liquid separation plate 1229a to the outside of the first processing container 1220a. The airflow flowing into the space between the sidewall of the first processing container 1220a and the gas-liquid separation plate 1229a is introduced into the gas-liquid separation plate 1229a. In this process, the processing liquid contained in the airflow is discharged from the discharging space to the outside of the first processing container 1220a through the discharge pipe 1228a, and the airflow is introduced into the exhaust space of the first processing container 1220a.

Although not illustrated, a lift driver for adjusting the relative heights of the first support plate 1242a and the first processing container 1220a may be provided.

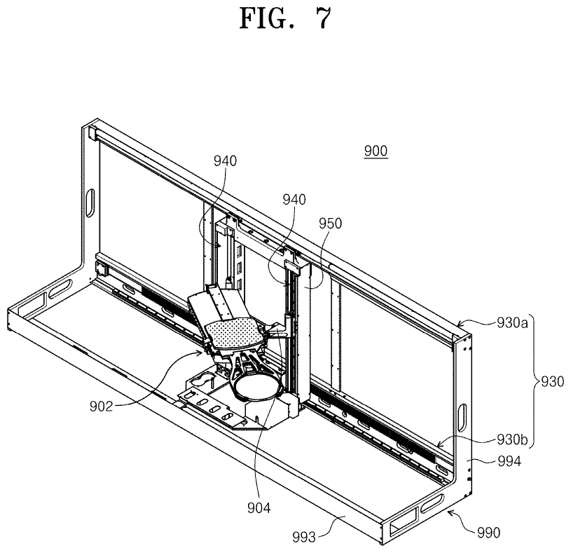

FIG. 7 is a perspective view illustrating an example of the transfer robot of FIG. 3.

Hereinafter, the robot 900 of FIG. 7 will be described as the transport robot of FIG. 3. However, alternatively, the transfer robot may be an index robot, and may optionally be another robot provided in the substrate processing apparatus 1.

Referring to FIG. 7, the transfer robot 900 may include a robot main body 902, a horizontal driving unit 930, and a vertical driving unit 940.

The robot main body 902 may include a hand 910 capable of moving forward and backward (X direction) and rotating (0 direction) by supporting the substrate, and a hand driving unit 920 including a base supporting the hand 910.

The hand driving unit 920 horizontally moves the hands 910, and the hands 910 are individually driven by the hand driving unit 920. The hand driving unit 920 includes a connecting arm 912 connected to an internal driving unit (not illustrated), and the hand 910 is installed at an end of the connecting arm 912. In the present exemplary embodiment, the transfer robot 900 includes two hands 910, but the number of hands 910 may increase according to the process efficiency of the substrate processing system 1000. A rotating unit (not illustrated) is installed under the hand driving unit 920. The rotating unit is coupled to the hand driving unit 920 and rotates to rotate the hand driving unit 920. Accordingly, the hands 910 rotate together.

The horizontal driving unit 930 and the vertical driving unit 940 are mounted on one body frame 990.

The body frame 990 may be provided in a form in which several frames are coupled to each other. The body frame 990 may include an upper horizontal driving unit 930a and a lower horizontal driving unit 930b for guiding the robot main body in the Y direction, a vertical auxiliary frame 992 erected in the vertical direction between the upper and lower horizontal driving units 930a and 930b, a horizontal auxiliary frame 993 extending in parallel to the lower horizontal driving unit 930b to form the body frame 990, an auxiliary frame 994 for coupling the upper and lower horizontal driving units 930a and 930b and the ends of the horizontal auxiliary frame 993 to each other to form a side shape of the body frame 990.

In this way, since the body frame 990 is coupled by a plurality of auxiliary frames 992, 993, and 994, the rigidity of the body frame 990 is strengthened, and thus durability is enhanced, such as being able to maintain the shape thereof completely even when used for a long time.

As described above, the horizontal driving units 930a and 930b are traveling guides for moving the robot main body 902 in the Y direction, and are coupled to both leading ends of the vertical driving unit 940. Among the horizontal driving units 930a and 930b, in particular, a horizontal driving unit (not illustrated) including a transfer belt is built in the inner surface of the lower horizontal driving unit 930b. Accordingly, the robot main body 902 is horizontally moved along the horizontal driving unit 930a and 930b by the driving of the transfer belt.

The vertical driving unit 940 is a type of traveling driving unit for moving the robot main body 902 in the Z direction, and is coupled to the horizontal driving units 930b and 930a. Accordingly, the robot main body 902 may be guided by the horizontal driving units 930b and 930a to move in the Y direction, and at the same time be guided by the vertical driving unit 940 to move in the Z direction. That is, the robot body 902 may be moved in an oblique direction corresponding to the sum of the Y direction and the Z direction.

On the other hand, the vertical driving unit 940 is formed of a plurality of frames, for example, two vertical frames, which are spaced apart from each other, so that the robot body 902 may freely enter and exit the space between the two frames.

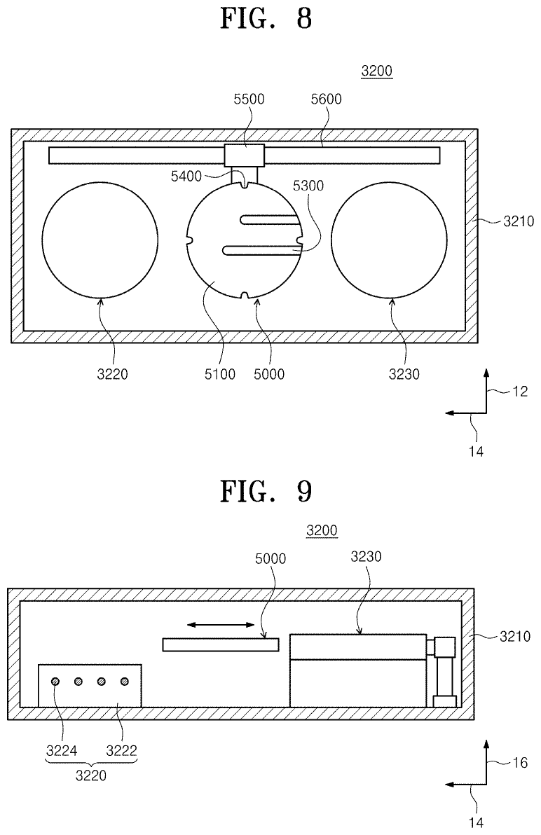

FIG. 8 is a top plan view schematically illustrating an example of the heat treatment chamber of FIG. 3, and FIG. 9 is a front view of the heat treatment chamber of FIG. 8.

Referring to FIGS. 8 and 9, the heat treatment chamber 3200 may include a housing 3210, a cooling unit 3220, a heating unit 3230, and a transfer unit 5000 having a transfer plate 5100.

The housing 3210 is provided in the shape of a generally rectangular parallelepiped. An inlet (not illustrated) through which the www enters and exits is formed on a lateral wall of the housing 3210. The inlet may remain open. Optionally, a door (not illustrated) may be provided to open and close the inlet. The cooling unit 3220, the heating unit 3230, and the transfer unit 5000 are provided in the housing 3210. The cooling unit 3220 and the heating unit 3230 are provided side by side along the second direction 14. According to an example, the cooling unit 3220 may be located closer to the transfer chamber 3400 than the heating unit 3230.

The cooling unit 3220 has a cooling plate 3222. The cooling plate 3222 may have a generally circular shape when viewed from the top. A cooling member 3224 is provided on the cooling plate 3222. According to an example, the cooling member 3224 is formed inside the cooling plate 3222 and may be provided as a flow path through which the cooling fluid flows.

The heating unit 3230 is provided as a device for heating the substrate to a temperature higher than room temperature. The heating unit 3230 heats the substrate W in a reduced pressure atmosphere at or lower than normal pressure. The heating unit 3230 may perform a baking process on the substrate W. The heating unit 3230 may be provided with a substrate processing apparatus 3300 that performs a bake process on the substrate W.

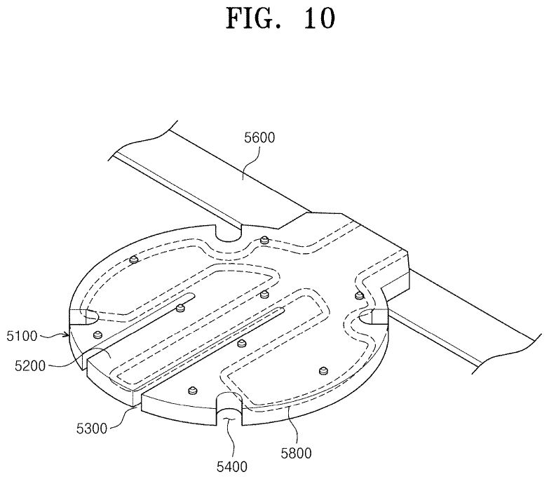

FIG. 10 is a diagram illustrating a transfer plate of FIG. 9.

Referring to FIGS. 8 to 10, the transfer plate 5100 may include a base plate 5200 and a refrigerant pipe 5800. The transfer plate 5100 may be a cooling plate that transfers the substrate W between the cooling unit 3220 and the heating unit 3230 in the heat treatment chamber 3200. In this case, the transfer plate 5100 may cool the substrate during the transfer process of the substrate W. Alternatively, the substrate W may be placed on the upper surface of the cooling plate 3222 of the cooling unit 3220 in a state in which the substrate W is placed on the base plate 5200.

The base plate 5200 is generally provided in a disk shape, and has a diameter corresponding to that of the substrate W. A notch 5400 is formed at an edge of the base plate 5200. The notches 5400 may have a shape corresponding to a protrusion 3429 formed on the hands 3420 of the transfer robots 3422 and 3424 described above. In addition, the notches 5400 are provided in a number corresponding to the number of protrusions 3429 formed on the hand 3420, and are formed at positions corresponding to the protrusions 3429. When the upper and lower positions of the hand 3420 and the base plate 5200 are changed in a position where the hand 3420 and the base plate 5200 are vertically aligned, the substrate W is transferred between the hand 3420 54 and the base plate 5200. The base plate 5200 is mounted on the guide rail 5600, and may be moved between a first region 3212 and a second region 3214 along the guide rail 5600 by the driving unit 5500.

A plurality of slit-shaped guide grooves 5300 are provided in the base plate 5200. The guide groove 5300 extends from the end of the base plate 5200 to the inside of the base plate 5200. The longitudinal direction of the guide groove 5300 is provided along the second direction 14, and the guide grooves 5300 are spaced apart from each other along the first direction 12. The guide groove 5300 prevents the base plate 5200 and lift pins 3325 from interfering with each other when the substrate W is transferred between the base plate 5200 and the heating unit 3230.

FIG. 11 is a diagram illustrating the substrate processing apparatus provided in the heating unit of FIG. 9.

Referring to FIG. 11, the heating unit 3230 may include a chamber 3310, a support unit 3320, a lifting unit 3360, and an airflow blocking member 3390.

The chamber 3310 may include an upper chamber 3312, a lower chamber 3314, and a sealing member 3316. The upper chamber 3312 may have a cylindrical shape with an open lower portion. The lower chamber 3314 may have a cylindrical shape with an open top. The lower chamber 3314 may be disposed below the upper chamber 3312. The upper chamber 3312 and the lower chamber 3314 may be combined with each other to form an inner space 3318.

Also, a sealing member 3316 may be provided between the upper chamber 3312 and the lower chamber 3314. The sealing member 3316 is positioned between the upper chamber 3312 and the lower chamber 3314. The sealing member 3316 allows the inner space 3318 to be sealed from the outside when the upper chamber 3312 is in contact with the lower chamber 3314. The sealing member 3316 may be provided in an annular ring shape. The sealing member 3316 may be fixedly coupled to the upper end of the lower chamber 3314.

The support unit 3320 supports the substrate W in the inner space 3318. In addition, the support unit 3320 is a heating plate capable of heating the substrate W. The support unit 3320 is fixedly coupled to the lower chamber 3314. The support unit 3320 may include a support plate 3322, a heater 3324, a lift pin 3325, and a support pin 3327.

The support plate 3322 is provided in a circular plate shape. The upper surface of the support plate 3322 may have a larger diameter than the substrate W. The upper surface of the support plate 3322 may function as a seating surface on which the substrate W is placed. In addition, the heater 3324 may be provided on the support plate 3322. The heater 3324 may heat the substrate W. In addition, a plurality of heaters 3324 may be provided. The plurality of heaters 3324 may heat the substrate W to a different temperature for each region. For example, some of the plurality of heaters 3324 may heat the center region of the substrate W to a first temperature, and other some of the plurality of heaters 3324 may heat middle and edge regions of the substrate W at a second temperature. The first temperature and the second temperature may be different from each other.

The lift pin 3325 may move the substrate W in the vertical direction. A plurality of lift pins 3325 may be provided. The lift pins 3325 may move the substrate W in the vertical direction when the substrate W is loaded into or unloaded from the inner space 3318.

The support pins 3327 may be provided on the upper portion of the support plate 3322. A plurality of support pins 3327 may be provided. The support pins 3327 may be provided to be spaced apart from each other. The support pins 3327 may support the bottom surface of the substrate W. The support pin 3327 may prevent the substrate W from directly contacting the support plate 3322.

An exhaust unit (not illustrated) may exhaust the inner space 3318. The exhaust unit may form airflow in the inner space 3318. The exhaust unit may form an ascending in the inner space 3318. An exhaust unit may be provided in the upper chamber 3312.

A gas supply unit (not illustrated) may supply gas to the inner space 3318. The gas supply unit may inject gas to the substrate W supported by the support unit 3320. The gas supplied by the gas supply unit may be outside air. The gas supplied by the gas supply unit may be clean air. The gas supplied by the gas supply unit may be gas of which temperature and humidity are controlled. The gas supply unit may form a descending in the inner space 3318. A gas supply unit may be provided in the upper chamber 3312.

The lifting unit 3360 may move any one of the upper chamber 3312 and the lower chamber 3314. For example, the lifting unit 3360 may move the upper chamber 3312 in the vertical direction. The lifting unit 3360 may move the upper chamber 3312 to an open position or a blocking position. The open position is a position in which the upper chamber 3312 and the lower chamber 3314 are spaced apart from each other and the inner space 3318 is opened. The blocking position is a position in which the inner space 3318 is sealed from the outside by the upper chamber 3312 and the lower chamber 3314.

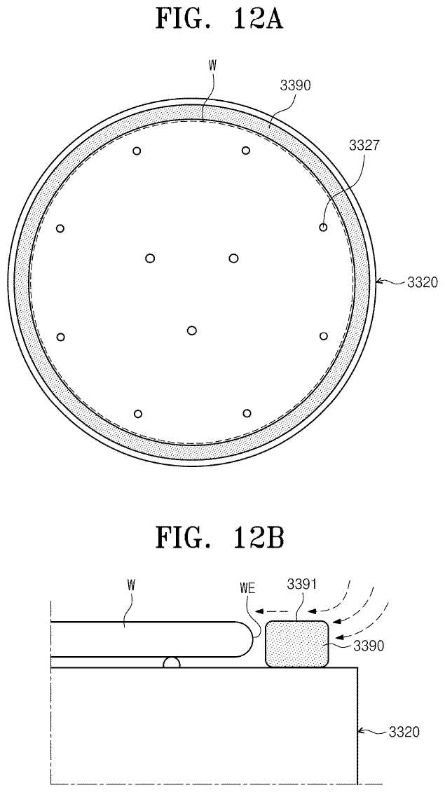

FIG. 12A is a diagram of the support unit of FIG. 11 when viewed from the top, and FIG. 12B is an enlarged diagram of the main part of FIG. 11.

Referring to FIGS. 12A and 12B, the airflow blocking member 3390 is provided on the upper surface of the support unit 3320. The airflow blocking member 3390 has an annular ring shape to surround the edge of the substrate. The airflow blocking member 3390 may block the surrounding airflow from approaching the edge of the substrate. It is preferable that the upper surface 3391 of the airflow blocking member 3390 is provided at a height that is the same as or higher than that of the upper surface of the substrate W seated on the support unit 3320.

FIG. 13 is a diagram illustrating an influence of the airflow blocking member on a temperature distribution of the edge of the substrate. In the drawing, the left side shows the temperature distribution of the edge of the substrate without the airflow blocking member, and the right side shows the temperature distribution of the edge of the substrate with the airflow blocking member.

As illustrated in FIG. 13, the airflow blocking member 3390 prevents the edge of the substrate from being directly exposed to the surrounding airflow when the substrate is heated, so that compared to the temperature of the edge of the substrate where the airflow blocking member 3390 is not present, the temperature decrease is small to minimize the temperature deviation.

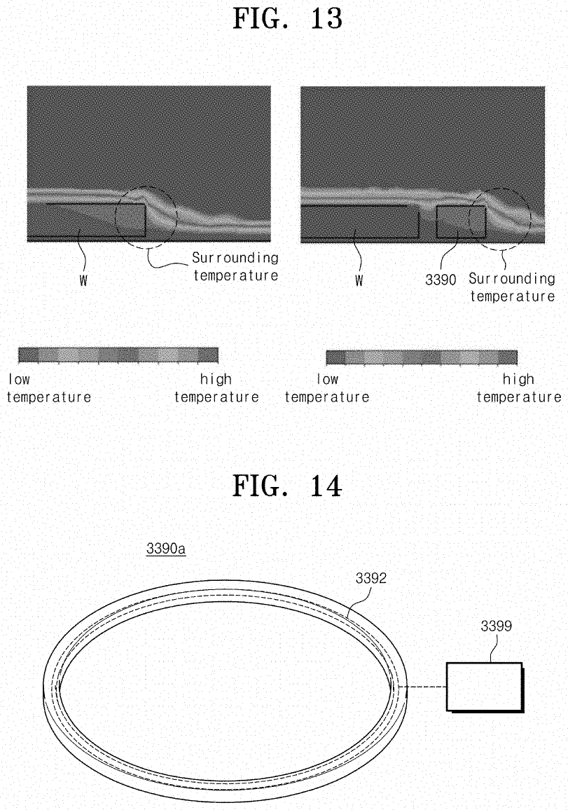

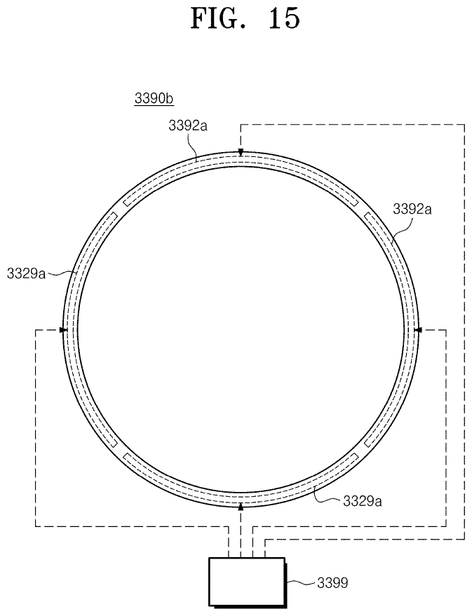

FIG. 14 is a diagram illustrating a second exemplary embodiment of the airflow blocking member.

Since an airflow blocking member 3390a illustrated in FIG. 14 is provided with a configuration and function substantially similar to the airflow blocking member 3390 illustrated in FIG. 12A, the second exemplary embodiment will be mainly described based on the differences from the present exemplary embodiment.

In the present exemplary embodiment, the airflow blocking member 3390a is characterized in including a heating element 3392 for preventing the temperature drop of the edge of the substrate. The heating element 3392 may be controlled by a controller 3399.

FIG. 15 is a diagram illustrating a modified example of the airflow blocking member.

Since an airflow blocking member 3390b illustrated in FIG. 15 is provided with a configuration and function substantially similar to the airflow blocking member 3390a illustrated in FIG. 14, the modified example will be mainly described based on the differences from the present exemplary embodiment.

In this modified example, the airflow blocking member 3390b is characterized in including a plurality of heating elements 3392a. The airflow blocking member 3390b may be divided into a plurality of sections, and a heating element 3392a may be provided in each section to be independently controllable by the controller 3399. Accordingly, the plurality of heating elements 3392a may heat the edge of the substrate to a different temperature for each section.

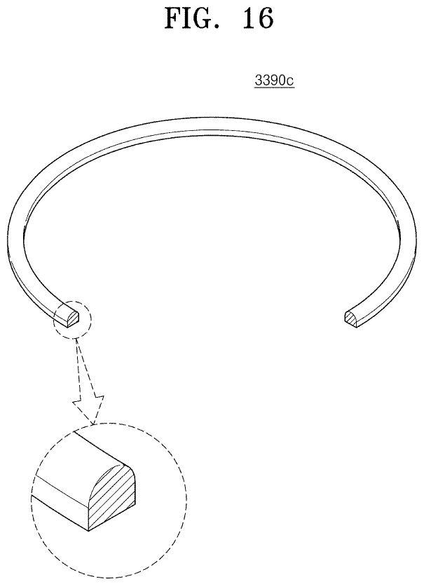

FIG. 16 is a view illustrating another modified example of the airflow blocking member.

As illustrated in FIG. 16, an airflow blocking member 3390c may have a hemispherical cross-sectional shape. The cross-sectional shape of the airflow blocking member 3390c is not limited thereto.

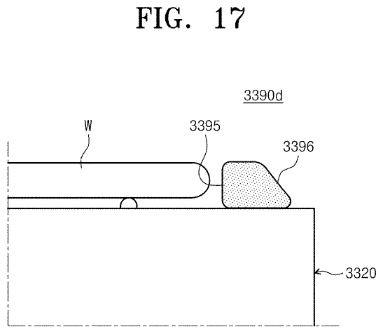

FIG. 17 is a view illustrating another modified example of the airflow blocking member.

As illustrated in FIG. 17, an airflow blocking member 3390d may be formed in which one side 3395 facing the edge of the substrate and the other side 3396 opposite to the one side 3395 have different inclinations from each other. The inclination of the other side 3396 may be provided more gently than the inclination of the one side 3395 to facilitate the flow of airflow approaching from the outside toward the substrate.

The foregoing exemplary embodiments are presented for helping the understanding of the present invention, and do not limit the scope of the present invention, and it should be understood that various modified exemplary embodiments from the foregoing exemplary embodiments are also included in the scope of the present invention. The technical protection scope of the present invention should be determined by the technical spirit of the claims, and it should be understood that the technical protection scope of the present invention is not limited to the literal description of the claims itself, but is substantially equivalent to the technical value.

What is claimed is:

1. A heat treatment unit, comprising:
a chamber providing a heat treatment space;
a heating plate which is provided inside the chamber and on which a substrate is seated; and
an airflow blocking member provided to the heating plate and provided to surround an edge of the substrate to block a surrounding airflow from approaching the edge of the substrate.

2. The heat treatment unit of claim 1, wherein the airflow blocking member includes a heating element for preventing a temperature drop of the edge of the substrate.

3. The heat treatment unit of claim 2, wherein the airflow blocking member is divided into a plurality of sections, and the heating element is provided in each section to be independently controllable.

4. The heat treatment unit of claim 2, wherein the airflow blocking member is provided in a ring shape.

5. The heat treatment unit of claim 2, wherein an upper surface of the airflow blocking member is provided at a height equal to or higher than a height of an upper surface of the substrate seated on the heating plate.

6. The heat treatment unit of claim 2, wherein the airflow blocking member has a curved upper surface.

7. The heat treatment unit of claim 2, wherein in the airflow blocking member, one side facing the edge of the substrate and the other side opposite to the one side have different inclinations from each other.

8. The heat treatment unit of claim 7, wherein the inclination of the other side is provided more gently than the inclination of the one side.

9. A substrate processing apparatus, comprising:
a process chamber in which an upper chamber and a lower chamber are in contact with each other to form a treatment space defined by the upper chamber and the lower chamber;
a heating plate positioned in the treatment space to heat a substrate;
a lift pin for placing the substrate on the heating plate or for moving the substrate placed on the heating plate to be spaced apart from the heating plate;
a driving member connected to the upper chamber or the lower chamber to vertically drive the upper chamber or the lower chamber;
an exhaust member connected to a central region of the upper chamber to exhaust the treatment space; and
an airflow blocking member provided on an upper surface of the heating plate and formed to surround an edge of the substrate so as to block a surrounding airflow from approaching the edge of the substrate.

10. The substrate processing apparatus of claim 9, wherein the airflow blocking member includes a heating element for preventing a temperature drop of the edge of the substrate.

11. The substrate processing apparatus of claim 10, wherein the airflow blocking member is divided into a plurality of sections, and the heating element is provided in each section to be independently controllable.

12. The substrate processing apparatus of claim 10, wherein the airflow blocking member has an annular ring shape.

13. The substrate processing apparatus of claim 10, wherein an upper surface of the airflow blocking member is provided at a height equal to or higher than a height of an upper surface of the substrate seated on the heating plate.

14. The substrate processing apparatus of claim 10, wherein the airflow blocking member has a curved upper surface.

15. The substrate processing apparatus of claim 10, wherein in the airflow blocking member, one side facing the edge of the substrate and the other side opposite to the one side have different inclinations from each other.

16. The substrate processing apparatus of claim 10, wherein the inclination of the other side is provided more gently than the inclination of the one side.

17. A substrate processing apparatus, comprising:
a housing providing a heat treatment space therein and having a slot for loading and unloading the substrate on one side;
a cooling unit located in the heat treatment space of the housing to cool the substrate;
a heating unit located at one side of the cooling unit and heating the substrate; and
a transfer unit for transferring a substrate between the cooling unit and the heating unit,
wherein the heating unit includes:
a process chamber in which an upper chamber and a lower chamber are in contact with each other to form a treatment space defined by the upper chamber and the lower chamber;
a heating plate positioned in the treatment space to heat a substrate;
a lift pin for placing the substrate on the heating plate or for moving the substrate placed on the heating plate to be spaced apart from the heating plate;
a driving member connected to the upper chamber or the lower chamber to vertically drive the upper chamber or the lower chamber;
an exhaust member connected to a central region of the upper chamber to exhaust the treatment space; and
an airflow blocking member provided on an upper surface of the heating plate and formed to surround an edge of the substrate so as to block a surrounding airflow from approaching the edge of the substrate.

18. The substrate processing apparatus of claim 17, wherein the airflow blocking member includes a heating element for preventing a temperature drop of the edge of the substrate.

19. The substrate processing apparatus of claim 18, wherein the airflow blocking member is divided into a plurality of sections, and the heating element is provided in each section to be independently controllable.

20. The substrate processing apparatus of claim 18, wherein the airflow blocking member has an annular ring shape, and
an upper surface of the airflow blocking member is provided at a height equal to or higher than a height of an upper surface of the substrate seated on the heating plate.
